(19) United States
(12) Patent Application Publication
(10) Pub. No.: US 2009/0115019 A1
(43) Pub. Date: May 7, 2009

(54) SEMICONDUCTOR DEVICE HAVING AIR GAP AND METHOD FOR MANUFACTURING THE SAME

(76) Inventors: Hyo Seok LEE, Gyeonggi-do (KR); Jong Min LEE, Gyeonggi-do (KR); Chan Bae KIM, Gyeonggi-do (KR); Chai O CHUNG, Gyeonggi-do (KR); Hyeon Ju AN, Gyeonggi-do (KR); Sung Kyu MIN, Seoul (KR)

Correspondence Address: LADAS & PARRY LLP, 224 SOUTH MICHIGAN AVENUE, SUITE 1600, CHICAGO, IL, 60604, US

(21) Appl. No.: 12/124,210

(22) Filed: May 21, 2008

(30) Foreign Application Priority Data
Nov. 5, 2007 (KR) 10-2007-0111987

(51) Int. Cl. H01L 21/764; H01L 21/76

(52) U.S. Cl. 257/522; 438/422; 257/E21.573

(57) ABSTRACT

The semiconductor device having an air gap includes an insulation layer formed on a semiconductor substrate and having a metal line forming region. A metal line is formed to fill the metal line forming region of the insulation layer. An air gap is formed between the insulation layer and the metal line.

### CROSS-REFERENCE TO RELATED APPLICATIONS

The present application claims priority to Korean patent application number 10-2007-0111987 filed on Nov. 5, 2007, which is incorporated herein by reference in its entirety.

### BACKGROUND OF THE INVENTION

The present invention relates to a semiconductor device and a method for manufacturing the same, and more particularly, to a semiconductor device which can reduce parasitic capacitance between adjoining metal lines and a method for manufacturing the same.

In a typical semiconductor device, metal lines are formed to electrically connect elements or lines with each other. Contact plugs, or vias, are formed to connect metal lines of one layer of a semiconductor device with metal lines of another layer of a semiconductor device. A current design trend is miniaturization of the semiconductor device. As the size of the semiconductor device decreases, the aspect ratio of a contact hole in which a contact plug is formed gradually increases. As a result, the difficulty and importance of a process for forming metal lines and contact plugs has been noted.

Aluminum (Al) and tungsten (W) have been mainly used as a material for the metal line of a semiconductor device since they have good electrical conductivity. Recently, a study has been conducted for using copper (Cu) for the metal line of a semiconductor device because Cu has excellent electrical conductivity and low resistance when compared to aluminum and tungsten, and therefore can solve the problems associated with RC signal delay in a highly integrated semiconductor device having a high operation speed.

A damascene process is employed to form a metal line using copper because copper cannot be easily dry-etched into a wiring pattern. In the damascene process, a metal line is formed by etching an insulation layer, defining a metal line forming region therein, and filling in the metal line region with a copper layer.

The metal line forming region is formed through a single damascene process or a dual damascene process. An upper metal line and a contact plug for connecting the upper metal line and a lower metal line can be simultaneously formed when applying the dual damascene process. Surface undulations that are produced due to the separate formation of the upper metal line and the contact plug can be eliminated when applying the dual damascene process, and therefore a subsequent process can be conveniently conducted.

Meanwhile, as the level of integration of a semiconductor device continues to increase, the interval between adjoining metal lines has decreases. Consequently, as the parasitic capacitance between the adjoining metal lines increases and RC signal delay exerts an adverse influence on the operation speed and the operation characteristics of the semiconductor device. In an effort to reduce the parasitic capacitance as described above, attempts have been made to use a low dielectric constant layer as an insulation substance for insulating the metal lines from one another, having a low dielectric constant of less than 2.8 in place of an SiO₂ layer having a dielectric constant of about 3.

However, although not described in detail, since the low dielectric constant layer markedly decreases in mechanical strength when compared to the generally-used dielectric layer, such as the SiO₂ layer. As such a subsequent chemical mechanical polishing (CMP) process for removing a portion of a metal layer, i.e., a copper layer, may cause serious defects in the low dielectric constant layer.

Therefore, adopting the low dielectric constant layer is not an appropriate method for reducing parasitic capacitance. Hence, a method for reducing parasitic capacitance in the manufacture of a highly integrated semiconductor device having a high operation speed has been demanded in the art.

### SUMMARY OF THE INVENTION

Embodiments of the present invention are directed to a semiconductor device which can reduce parasitic capacitance between adjoining metal lines and a method for manufacturing the same.

Also, embodiments of the present invention are directed to a semiconductor device which can reduce resistance and capacitance (RC) delay through reduction of parasitic capacitance and a method for manufacturing the same.

In one aspect, a semiconductor device comprises an insulation layer formed on a semiconductor substrate and having a metal line forming region, a metal line formed to fill the metal line forming region of the insulation layer, and an air gap formed between the insulation layer and the metal line.

The metal line forming region has a single structure of a trench or a double structure of a via-hole and a trench.

The insulation layer comprises any one of an SiO₂ layer, an SiOCH layer, an SiOH layer, and a low dielectric constant layer having a dielectric constant of 2.4˜2.8.

The metal line comprises a diffusion barrier layer.

The diffusion barrier layer has a single layer structure or a double layer structure.

The metal line comprises a copper layer.

The semiconductor device further comprises an etch stop layer formed on the metal line, the air gap, and the insulation layer.

The etch stop layer comprises an SiN layer or an SiC layer.

In another aspect, a method for manufacturing a semiconductor device comprises the steps of forming an insulation layer having a metal line forming region, on a semiconductor substrate, forming a sacrificial layer on a surface of the metal line forming region and the insulation layer, forming a diffusion barrier layer on the sacrificial layer, forming a metal layer on the diffusion barrier layer to fill the metal line forming region, removing the metal layer, the diffusion barrier layer and the sacrificial layer until the insulation layer is exposed, and thereby forming a metal line in the metal line forming region, forming an etch stop layer on the insulation layer, the sacrificial layer, the diffusion barrier layer and the metal line, and removing the sacrificial layer and thereby forming an air gap between the insulation layer and the metal line including the diffusion barrier layer.

The metal line forming region has a single structure of a trench or a double structure of a via-hole and a trench.

The insulation layer comprises any one of an SiO₂ layer, an SiOCH layer, an SiOH layer, and a low dielectric constant layer having a dielectric constant of 2.4˜2.8.

The sacrificial layer is formed of a thermally degradable polymer (TDP) substance.

The TDP substance includes a poly methyl meth acrylate (PMMA)-based polymer.

The TDP substance includes any one of poly ethylene oxide (PEO)—poly propylene oxide (PPO)—poly ethylene oxide (PEO) triblock copolymers.

The TDP substance includes polycaprolactone (PCL).

The TDP substance is applied through a chemical vapor deposition (CVD) process or an spin-on dielectric (SOD) process.

The SOD process is conducted at a temperature of 50˜400° C. in the range of 100˜3,000 RPM by adding air or nitrogen into the TDP substance.

The diffusion barrier layer has a single layer structure or a double layer structure.

The metal layer comprises a copper layer.

The etch stop layer comprises an SiN layer or an SiC layer.

The removal of the sacrificial layer is implemented by annealing the sacrificial layer so that the sacrificial layer is decomposed to a vapor phase and is thereby removed.

Annealing is conducted at a temperature of 400˜500° C.

### BRIEF DESCRIPTION OF THE DRAWINGS

FIG. 1 is a cross-sectional view illustrating a semiconductor device in accordance with an embodiment of the present invention.

FIGS. 2A through 2D are cross-sectional views illustrating the processes of a method for manufacturing a semiconductor device in accordance with another embodiment of the present invention.

### DESCRIPTION OF SPECIFIC EMBODIMENTS

In the present invention, an air gap is formed between a metal line including a diffusion barrier layer and an insulation layer when forming a metal line through a damascene process using copper as a wiring substance, by depositing and annealing a sacrificial layer made of a substance such as thermally degradable polymer (TDP), which can be decomposed to a vapor phase through annealing.

As discussed above, the conventional semiconductor device, may utilize a low dielectric constant layer having a dielectric constant less than 2.8 is adopted to reduce parasitic capacitance, however, the low dielectric constant layer has poor mechanical strength. In the semiconductor device according to the present invention the parasitic capacitance between adjoining metal lines can be reduced through the formation of an air gap even when the generally-used dielectric layer is adopted, as opposed to the low dielectric constant layer having poor mechanical strength of the conventional semiconductor device described above. Accordingly, in the present invention, resistance and capacitance (RC) signal delay can be reduced because the parasitic capacitance can be effectively reduced, and therefore, it is possible to realize a semiconductor device which operates at a high speed.

Further, reproducibility and stability in a semiconductor device manufacturing process can be secured in the present invention, because the air gap can be formed through an annealing process without additionally conducting a masking process. In addition, the dielectric constant of the insulation layer can be easily adjusted in the present invention, because the thickness of the air gap can be adjusted according to the thickness of the TDP layer.

Hereafter, the specific embodiments of the present invention will be described with reference to the attached drawings.

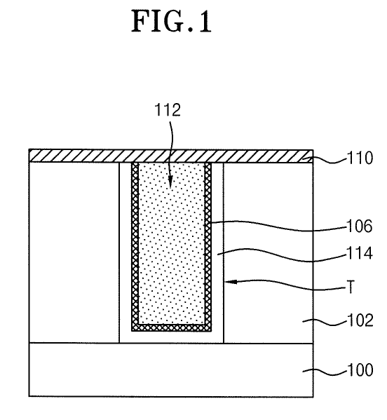

FIG. 1 is a cross-sectional view illustrating a semiconductor device in accordance with an embodiment of the present invention. Referring to FIG. 1, an insulation layer 102 having a metal line forming region T is formed on a semiconductor substrate 100. A metal line 112 composed of a metal layer (for example a copper layer) is formed in the metal line forming region T. The metal line comprises a diffusion layer 106. The diffusion barrier layer 106 has a single layer structure or a double layer structure (for example a Ti, TiN or Ti/TiN). An air gap 114 is formed between the insulation layer 102 and the metal line 112. An etch stop layer 110, to be used in subsequent processes, is formed on the insulation layer 102, the air gap 114 and the metal line 112.

Preferably, the insulation layer 102 comprises a layer which has the same molecular composition as an SiO₂ layer or an SiOCH layer, or an SiOH layer formed by using SiH₄ or tetraethoxysilane (TEOS) as a precursor and a low dielectric characteristic. In order to further reduce the parasitic capacitance between adjoining metal lines 112, the insulation layer 102 may comprise a low dielectric constant layer which has a dielectric constant of 2.4˜2.8 and includes fine pores. The etch stop layer 110 comprises an SiN layer or an SiC layer.

The metal line forming region T is defined through a single damascene process to have a single structure of a trench. Alternatively, the metal line forming region T can be defined through a dual damascene process to have a double structure of a via-hole and a trench. The metal line 112 is secured by the etch stop layer 110.

In the semiconductor device according to the present invention configured as described above, the parasitic capacitance between adjoining metal lines can be reduced due to the presence of the air gap formed between the insulation layer and the metal line including the diffusion barrier layer, and therefore, RC signal delay can be reduced.

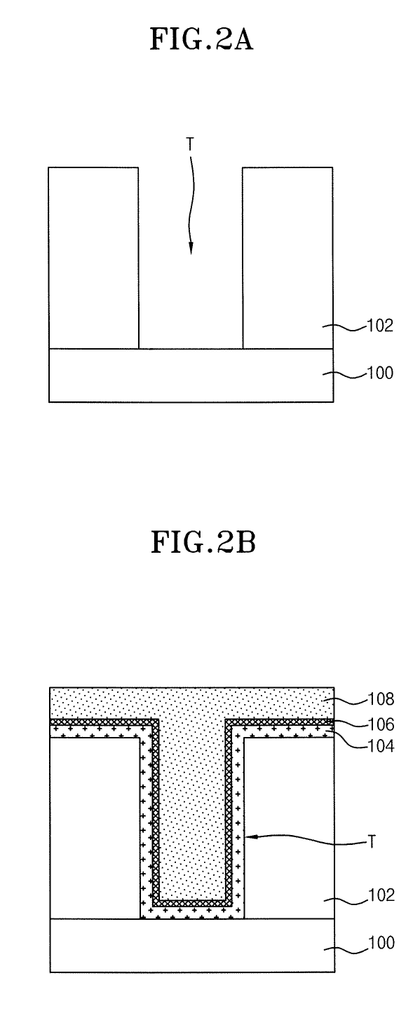

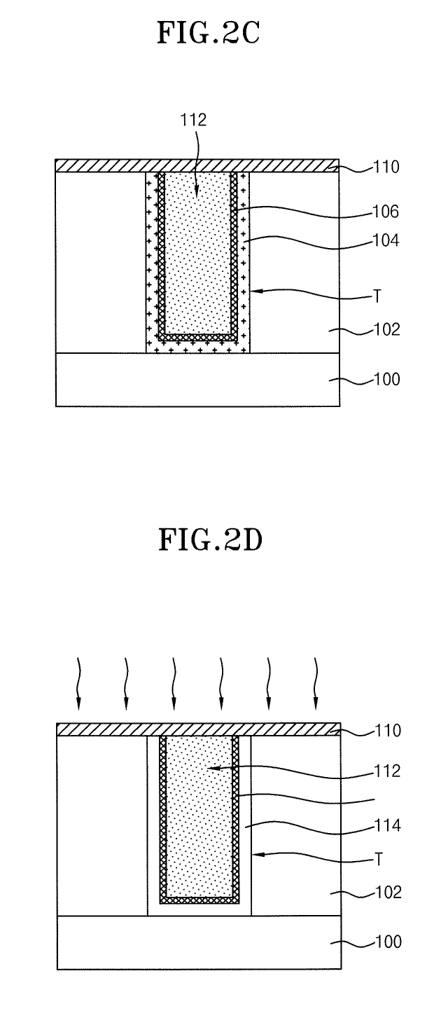

FIGS. 2A through 2D are cross-sectional views illustrating a method for manufacturing a semiconductor device in accordance with another embodiment of the present invention.

Referring to FIG. 2A, an insulation layer 102 is formed on a semiconductor substrate 100 which has a bottom structure (not shown) including gates and capacitors. After forming a mask pattern (not shown) on the insulation layer 102, a metal line forming region T in which a metal line is to be formed is defined by etching the insulation layer 102 using the mask pattern as an etch mask. The mask pattern is removed after the metal line forming region T is defined.

The insulation layer 102 comprises a layer which has the same molecular composition as an SiO₂ layer or an SiOCH layer, or an SiOH layer formed by using SiH₄ or TEOS as a precursor and a low dielectric characteristic, or a low dielectric constant layer which includes fine pores and has a dielectric constant less than 2.8, for example, of 2.4˜2.8. The metal line forming region T is defined through a single damascene process to have a single structure of a trench. Alternatively, the metal line forming region T can be defined through a dual damascene process to have a double structure of a via-hole and a trench.

Referring to FIG. 2B, a sacrificial layer 104 is formed on both the surface of the metal line forming region T and the insulation layer 102. For example, the sacrificial layer 104 may be made of a TDP substance. The TDP substance includes a polymethylmethacrylate (PMMA)-based polymer. Also, the TDP substance may include any one of polyethylene oxide-polypropylene oxide-polyethylene oxide (PEO-PPO-PEO) triblock copolymers. In addition, the TDP substance may include PCL (polycaprolactone). The sacrificial layer 104, made of the TDP substance, is formed through a chemical vapor deposition (CVD) process or an spin-on dielectric (SOD) process. The SOD process is conducted at a temperature of 50˜400° C. in the range of 100˜3,000 RPM by adding air or nitrogen into the TDP substance.

A diffusion barrier layer 106 is formed on the sacrificial layer 104. For example, the diffusion barrier layer 106 is formed with a single layer structure of Ti or TiN, and a double layer structure of Ti/TiN. A copper layer 108 is formed on the diffusion barrier layer 106 to fill the metal line forming region T. The copper layer 108 is formed by sequentially conducting a seed layer forming process using physical vapor deposition (PVD) and a plating process.

Referring to FIG. 2C, portions of the copper layer 108, the diffusion barrier layer 106 and the sacrificial layer 104 are removed through chemical mechanical polishing (CMP) until the insulation layer 102 is exposed, and through this, a metal line 112, which fills the metal line forming region T and comprises the copper layer 108, is formed. An etch stop layer 110 that will be used in subsequent processes is formed on the insulation layer 102, the sacrificial layer 104, the diffusion barrier layer 106 and the metal line 112. The etch stop layer 110 is formed as an SiN layer or an SiC layer through a CVD process or an SOD process.

Referring to FIG. 2D, the resultant semiconductor substrate 100, which is formed with the etch stop layer 110, is annealed at a temperature of 400˜500° C. During annealing, the sacrificial layer 104 is decomposed to a vapor phase and therefore removed. As a result, an air gap 114 is formed in the space which is defined by the removal of the sacrificial layer 104. That is, the air gap 114 is formed between the insulation layer 102 and the metal line 112 including the diffusion barrier layer 106. The thickness of the air gap 114 can be adjusted by adjusting the thickness of the sacrificial layer 104. According to this, by adjusting the thickness of the air gap 114, the parasitic capacitance between adjoining metal lines 112 can be adjusted.

Thereafter, while not shown in the drawings, by sequentially implementing a series of subsequent well-known processes, the manufacture of a semiconductor device according to the present invention is completed.

As is apparent from the above description, in the present invention, by forming an air gap between an insulation layer and a metal line, the parasitic capacitance between adjoining metal lines can be effectively reduced without using a low dielectric constant layer having poor mechanical strength. Accordingly, in the present invention, RC signal delay can be decreased, because the parasitic capacitance can be effectively reduced. Specifically, in the present invention, the desired dielectric constant of the insulation layer can be easily adjusted, because the thickness of the air gap can be adjusted through only adjusting the thickness of a sacrificial layer.

Further, in the present invention, reproducibility and stability of processes can be secured since the air gap can be formed only through annealing without additionally conducting a masking process.

Although specific embodiments of the present invention have been described for illustrative purposes, those skilled in the art will appreciate that various modifications, additions and substitutions are possible, without departing from the scope and the spirit of the invention as disclosed in the accompanying claims.

What is claimed is:

1. A semiconductor device having an air gap, the semiconductor device comprising:
an insulation layer formed on a semiconductor substrate and having a metal line forming region;
a metal line formed to fill the metal line forming region of the insulation layer; and
the air gap formed between the insulation layer and the metal line.

2. The semiconductor device according to claim 1, wherein the metal line forming region has a single structure of a trench or a double structure of a via-hole and a trench.

3. The semiconductor device according to claim 1, wherein the insulation layer comprises any one of an SiO₂ layer, an SiOCH layer, an SiOH layer, and a low dielectric constant layer having a dielectric constant of 2.4˜2.8.

4. The semiconductor device according to claim 1, wherein the metal line comprises a copper layer.

5. The semiconductor device according to claim 1, wherein the metal line comprises a diffusion barrier layer.

6. The semiconductor device according to claim 5, wherein the diffusion barrier layer has a single layer structure or a double layer structure.

7. The semiconductor device according to claim 1, further comprising:
an etch stop layer formed on the metal line, the air gap, and the insulation layer.

8. The semiconductor device according to claim 1, wherein the etch stop layer comprises an SiN layer or an SiC layer.

9. A method for manufacturing a semiconductor device, comprising the steps of:
forming an insulation layer having a metal line forming region on a semiconductor substrate;
forming a sacrificial layer on a surface of the metal line forming region and the insulation layer;
forming a diffusion barrier layer on the sacrificial layer;
forming a metal layer on the diffusion barrier layer to fill the metal line forming region;
removing a portion of the metal layer, a portion of the diffusion barrier layer and a portion the sacrificial layer until the insulation layer is exposed, and thereby forming a metal line in the metal line forming region;
forming an etch stop layer on the insulation layer, the sacrificial layer, the diffusion barrier layer and the metal line; and
removing the sacrificial layer and thereby forming an air gap between the insulation layer and the metal line including the diffusion barrier layer.

10. The method according to claim 9, wherein the metal line forming region has a single structure of a trench or a double structure of a via-hole and a trench.

11. The method according to claim 9, wherein the insulation layer comprises any one of an SiO₂ layer, an SiOCH layer, an SiOH layer, and a low dielectric constant layer having a dielectric constant of 2.4˜2.8.

12. The method according to claim 9, wherein the sacrificial layer is formed of a thermally degradable polymer (TDP) substance.

13. The method according to claim 12, wherein the TDP substance includes a polymethylmethacrylate (PMMA)-based polymer.

14. The method according to claim 12, wherein the TDP substance includes any one of polyethylene oxide-polypropylene oxide-polyethylene oxide (PEO-PPO-PEO) triblock copolymers.

15. The method according to claim 12, wherein the TDP substance includes polycaprolactone (PCL).

16. The method according to claim 12, wherein the TDP substance is applied through a chemical vapor deposition (CVD) process or a spin-on dielectric (SOD) process.

17. The method according to claim 16, wherein the SOD process is conducted at a temperature of 50˜400° C. in the range of 100˜3,000 RPM by adding air or nitrogen into the TDP substance.

18. The method according to claim 9, wherein the diffusion barrier layer has a single layer structure or a double layer structure.

19. The method according to claim 9, wherein the metal layer comprises a copper layer.

20. The method according to claim 9, wherein the etch stop layer comprises an SiN layer or an SiC layer.

21. The method according to claim 9, wherein the removal of the sacrificial layer is implemented by annealing the sacrificial layer so that the sacrificial layer is decomposed to a vapor phase and is thereby removed.

22. The method according to claim 21, wherein annealing is conducted at a temperature of 400˜500° C.
